(19) United States
(12) Patent Application Publication
(10) Pub. No.: US 2011/0140088 A1
(43) Pub. Date: Jun. 16, 2011

(54) PHASE COHERENT SOLID STATE ELECTRON GYROSCOPE ARRAY

(76) Inventors: Christopher Search, Montclair, NJ (US); Eui-Hyeok Yang, Fort Lee, NJ (US); Stefan Strauf, Ridgewood, NJ (US)

(21) Appl. No.: 12/908,419

(22) Filed: Oct. 20, 2010

Related U.S. Application Data
(60) Provisional application No. 61/253,095, filed on Oct. 20, 2009.

(51) Int. Cl. H01L 29/12; H01L 21/02

(52) U.S. Cl. 257/29; 438/48; 257/E29.068; 257/E21.002

(57) ABSTRACT

An apparatus and method is disclosed which may comprise an electron gyroscope, which may comprise an interferometer array which may comprise interferometer rings formed from a sheet of graphene. Each interferometer ring in the interferometer array may have a half-circumference shorter in length than the ballistic length for an electron in graphene.

### RELATED CASES

The present application claims priority to U.S. Provisional Application No. 61/253,095, entitled PHASE COHERENT SOLID STATE ELECTRON GYROSCOPE ARRAY, filed on Oct. 20, 2009, the contents of which are hereby incorporated by reference.

### FIELD OF INVENTION

The present invention relates to rotation detection, including inertial rotation detection, and, more particularly, to a device for detecting rotation, such as inertial rotation, using electron interferometry in graphene.

### BACKGROUND OF THE INVENTION

Current interferometric gyroscopes based on the Sagnac effect use either light or atomic matter waves (i.e. the quantum mechanical wave behavior of all matter). Atom interferometric gyroscopes are extremely bulky because of the need to operate in a vacuum and at temperatures of around 1 micro-Kelvin or less. Optical gyroscopes are much more compact but still weigh at least a kilogram and have a size and weight limited by the need to use either several kilometers of optical fiber or a large area, high quality ring cavity.

Atom gyroscopes are still in the prototype stage at a number of universities (Stanford, Harvard, MIT, U. of Colorado, JPL, and several groups in Germany) and will most likely not find use outside of advanced military applications in the foreseeable future because of their bulk. Optical gyroscopes have been in commercial use for approximately thirty (30) years primarily for inertial navigation in aircraft and sea vessels and for military positioning/stabilization applications. Another major gyroscope technology in commercial use is micro-electromechanical systems (“MEMS”). MEMS gyroscopes detect changes in the motion of vibrating masses due to rotation of the MEMS gyroscope. The Coriolis force creates this change.

Graphene is a one-atom-thick planar sheet of carbon atoms that are densely packed in a honeycomb crystal lattice. Graphene is the basic structural element of some carbon allotropes including graphite (many graphene sheets stacked together), carbon nanotubes and fullerenes. It can also be considered as an infinitely large aromatic molecule, the limiting case of the family of flat polycyclic aromatic hydrocarbons called graphenes.

Carbon nanotubes (CNTs; also known as buckytubes) are allotropes of carbon with a cylindrical nanostructure. Nanotubes are members of the fullerene structural family, which also includes the spherical buckyballs. The ends of a nanotube may be capped with a hemisphere of the buckyball structure. Their name is derived from their size, since the diameter of a nanotube is on the order of a few nanometers, while currently they can be up to 18 centimeters in length. Nanotubes are categorized as single-walled nanotubes (SWNTs) and multi-walled nanotubes (MWNTs).

### SUMMARY OF THE INVENTION

An electron gyroscope is disclosed that comprises a chain of microscopic ring-shaped interferometers with radii of 1-10 micrometers, which are fabricated in graphene. The invention represents a new method for detecting inertial rotations using electron interferometry in graphene. Compared to other approaches based on optical gyroscopes, the proposed device offers comparable sensitivity to optical gyroscopes in a package that is up to one million times smaller (i.e., a chip-scale gyro device) and is mass producible using standard lithographic processes. The device can be fabricated in high mobility conductors, which would allow phase coherent propagation of electron de Broglie waves over the full extent of the device size of about one micron. The device can also be fabricated by using a atomic force microscopy tip or nanomanipulator tip, such as a layer of polydimethylsiloxane (“PDMS”) to exfoliate a layer(s) of graphene from a source of graphene, such as a highly ordered pyrolyzed graphite (“HOPG”) block and pressure stamping the layer onto a suitable substrate, such as a Si substrate.

### BRIEF DESCRIPTION OF THE DRAWINGS

For a more complete understanding of the present invention, reference is made to the following detailed description of the invention considered in conjunction with the accompanying drawings, in which:

FIG. 1 is a partly schematical representation of a electron gyroscope fabricated in graphene according to aspects of an embodiment of the disclosed subject matter;

FIGS. 2a-d show schematically a portion of a manufacturing process for forming an electron gyroscope according to aspects of an embodiment of the disclosed subject matter.

### DETAILED DESCRIPTION OF THE INVENTION

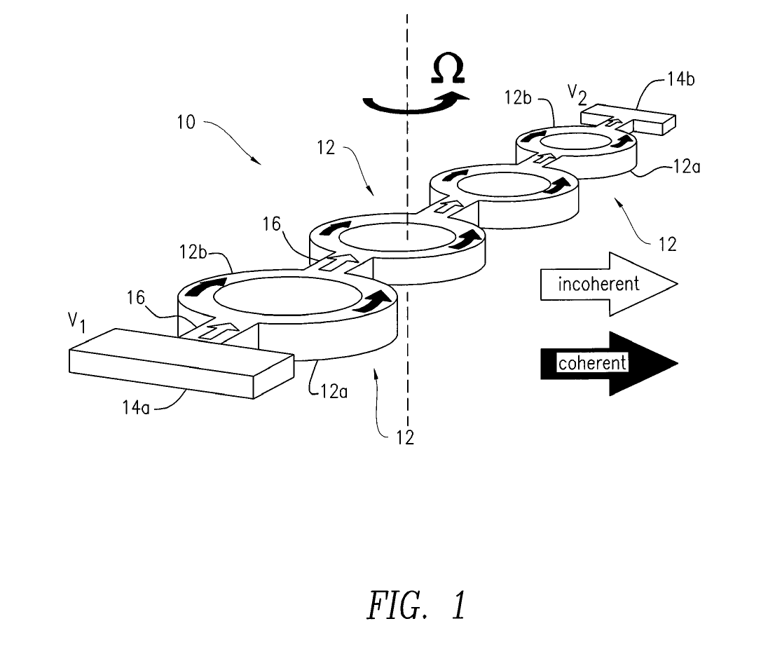

Referring to FIG. 1, an electron gyroscope which may be composed of an array 10 of microscopic ring-shaped interferometer rings 12 with radii of 1-10 micrometers, such as a chain of such rings 12, which are fabricated in graphene. Despite the much smaller size in comparison to optical counterparts, they achieve comparable sensitivity because the Sagnac phase shift for electrons is 100,000-1,000,000 times larger than for light (the exact value depends on the effective mass and Fermi velocity of the material). The micron scale and solid state implementation offer the following advantages: (a) ultra-compact gyroscopes that have dimensions and weight many times smaller than current commercial optical gyroscopes; and (b) ability to build these gyroscopes directly on microchips and interface the signal from the gyro with additional electrical circuits on the same microchip.

Rotational motion is detected via a phase shift between two arms 12a, 12b of each ring 12 of the interferometer array 10, which is attached at opposed ends to electrical leads 14a, 14b, respectively, with an applied voltage (V1 and V2) on the respective leads 14a, 14b. The phase shift is a consequence of the Sagnac effect, discovered in 1913, which is also the basis for current optical gyroscopes that have been in commercial use for approximately thirty (30) years. The phase shift between the arms 12a, 12b of the electron interferometer array 10 results in a modulation of the electrical current at the outgoing lead 14b of the interferometer array 10. The modulation of the current follows from the fact that the conductivity (inverse of resistance) is proportional to the quantum mechanical transmission probability through the respective rings 12. From the amount of the modulation, the rate of rotation can be determined.

The phase shift is proportional to both the rotation rate (Ω) and the area enclosed by each electron gyroscope ring 12 of the interferometer array 10. A single ring 12 with a radius of 1-10 micrometers produces a phase shift that is so small that the modulation of the current is less than the intrinsic noise, and, hence, undetectable. However, employing conductive connectors 16 to cascade the individual interferometer rings 12 into a serial interferometer array 10, as illustrated partly schematically in FIG. 1, one can achieve a dramatic enhancement in the overall current modulation for the full interferometer array 10. The conductive connectors 16 may also be formed of graphene, like the individual rings 12 themselves.

The aforementioned enhancement is a consequence of quantum mechanical interference between rings 12. The phase of the electron waves in each ring 12 is determined by the Sagnac effect for that ring 12, and the phase shifts from the individual rings 12 interfere in such a way that the total transmission through the interferometer array 10 (linear chain of rings 12) exhibits periodic transmission windows and regions of zero transmission as a function of rotation rate Ω. At the edges of the transmission windows, the transmission probability changes from 0 to 1 (and hence the current goes from 0 to maximal) with a slope that is proportional to N², where N is the number of rings 12. The edges of the transmission windows, which occur periodically at specific rotation rates, can be tuned to any arbitrary “window” of inertial rotation that one desires to detect by either proper fabrication of the shape of the rings 12 (e.g., introducing an asymmetry in the length of the two arms 12a, 12b of the rings 12 of the interferometer array 10) or actively by either an electric or magnetic field applied to one or more of the rings 12.

By contrast, it is noted that a serial array of electron interferometers where transport between rings is incoherent results in a signal that is approximately the signal for a single ring times N^{1/2}. This implies that for the same number of rings, the quantum interference between rings leads to a signal that is N^{3/2} times longer than incoherent “classical” transport between rings. For incoherent “classical” transport, one would need between 10⁶ and 10⁷ rings to achieve a signal to noise ratio >1 for sub-Hertz rotations. For phase coherent quantum transport between rings 12 of the interferometer array 10, through the conductive connectors 16, one could achieve the same SNR with 10-100 rings.

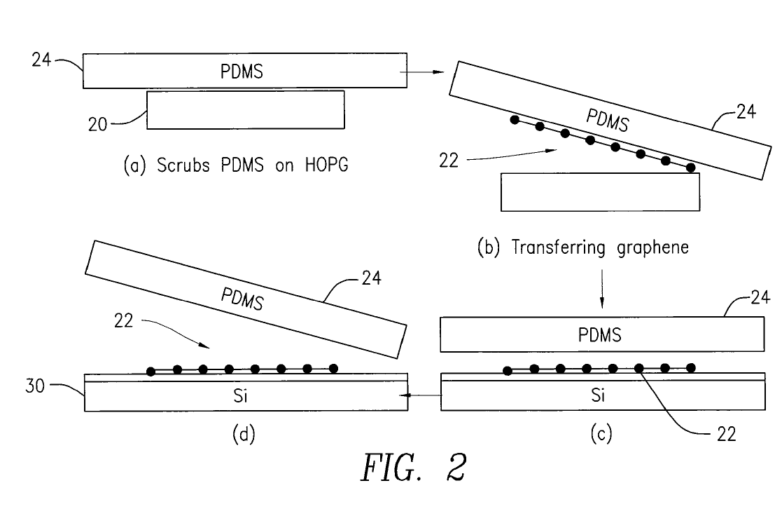

Single or few layer graphene flakes up to 1000 microns in size can be obtained from bulk graphene by using adhesive tape in a process known as mechanical exfoliation, as illustrated schematically in FIGS. 2a-2d. Despite the simplicity of the method, mechanical exfoliation provides high-quality material with record high mobilities and transport in the ballistics regime over several microns. As illustrated schematically in FIGS. 2a-2d, a small area of graphene film can be easily exfoliated mechanically from highly-ordered pyrolyzed graphite (“HOPG”) 20 (see FIGS. 2a-2b) and transferred onto a Si/SiO₂ substrate 30 (see FIGS. 2c-2d).

Fabrication of graphene ring structures may combine several techniques, including mechanical cleavage, whereby a single layer or a few layers of graphene in sheet form 22 (see FIGS. 2a-2d) may be obtained by mechanical separation from bulk graphite, such as the highly organized pyrolyzed graphite (“HOPG”) block 20 (see FIGS. 2a-2b). Prior aqueous dispersion, as discussed in Nature Nanotechechnology, 3, 101 (2008), hereby incorporated by reference, may be used to reduce electron mobility to about 500 cm²/V-s (compared to 15,000 cm²/V-s from mechanical exfoliation only). As shown in FIGS. 2a-2d, a combination of 1) mechanical cleavage (FIG. 2b), 2) polydimethysiloxane (“PDMS”) stamping (FIG. 2c), and 3) thermal treatment may be used to obtain a graphene layer(s) on a substrate for fabricating the proposed rotation-detection nano-device sheet or tube from which to fabricate the interferometer array 10, as discussed below. Mechanical cleavage is incorporated into the PDMS stamping technique which utilizes a PDMS layer 24 (see FIGS. 2b-2d) to transfer the graphene layer from the (“HOPG”) block 20 to the target substrate 30, as shown in FIGS. 2a-2d.

Referring to FIGS. 2a-2d, initially, a PDMS layer 20 may be applied to an HOPG block 24 (FIG. 2a) and pulled off (FIG. 2b) with a force sufficient to exfoliate the selected number of graphene layers 22, as is well known in the art, as discussed, e.g., in Applied Physics Letters, 86, 073104 (2005), incorporated herein by reference. In this case, as an example, the PDMS layer 20 may be used substantially as an atomic force microscopy (“AFM”) tip or a nanomanipulator tip to control the exfoliation force and thus the thickness/number of the exfoliated graphene layers. The PDMS layer 20 with exfoliated graphene layer 22 is then affixed to the target substrate 30 (see FIG. 2c) where the application of pressure as well as thermal treatment can also be used to control the thickness (number of layers) of the graphene layer 22 transferred to the substrate 30, such as a Si substrate (see FIG. 2d).

Van der Waals forces may be created during the pressure application between the graphene 22 and target substrate 30, which may be sufficient to form a sturdy bond at this interface. Thermal treatment may be necessary to detach the PDMS layer 24 (see FIG. 2d). The mismatch in the coefficients of thermal expansion between the PDMS layer 20 and the graphene layer 22 may also be utilized to facilitate the detachment of the PDMS layer 20 upon the application of heat.

Thereafter, the graphene, as well as metal electrodes, may be patterned using, e.g., e-beam lithography and plasma etching or any other suitable micro-lithography technique. Using this reproducible and controllable fabrication technique, large-scale production of lithographically defined graphene nanostructures is possible.

The ultimate resolution of electron beam lithography (“EBL”) depends on many factors, such as, the resist thickness, resist dilution, spin-coating speed, beam current, and dose, all of which need to be optimized. The graphene flakes deposited onto SiO₂ can be spun with hydrogen silsesquioxane HSQ material and the desired pattern (ribbons or rings) defined by the electron beam lithography. Unexposed areas of HSQ can be removed based on a potassium-hydroxide based developer. The pattern can be transferred by reactive ion etching into the graphene flake and the cross-linked resist can be stripped by hydrofloric acid HF wet etching. Electric contacts to graphene can be fabricated by another EBL step based on Poly(methyl methacrylate (“PMMA”). After development, a layer of Cr/Ti/Au can be deposited to form the contacts and the PMMA layer can be removed by liftoff. A 10 nm aluminum oxide layer can be used to encapsulate the resultant structure and to provide a gate oxide for the formation of a top-gate.

A second class of materials may be utilized to take advantage of the ballistic nature of electron transport in such materials as carbon, e.g., in the form of multi-wall and single-wall carbon nanotubes (“MWCNT”, “SWCNT”) as well as multi-dimensional, e.g., 2 dimensional, layers of graphene which may be processed into the desired ring-shape to form the rings 12 of the electron interferometer array 10 by semiconductor manufacturing photo-lithography or electron beam lithography (“EBL”), or other suitable micro-lithography technique as applicable.

As an alternative, e.g., in case of a CNT-based ring 12 structure, a fabrication procedure (not shown) may be as follows. The configuration and dimensions of individual nanodimples may be defined on a photo-resist layer to define an exposed area, as is known in the art, which exposed area can then be selectively etched, such as by reactive ion etching (“REI”), to a desired depth. A high-throughput colloidal deposition technique, such as is discussed in T. Kraus, et al., Nature Nanotechnology, 10, 1038 (2007), incorporated herein by reference, may then be used to deposit uniquely functionalized nanoparticles that can be specifically self-assembled onto corresponding nanodimples.

This may be done with a form of nano-printing, combining photolithography or other lithography to form a pattern in one substrate which is filled with nano-particles of a certain material, such as carbon, and then transferred (printed) to another substrate, such as, a Si substrate, for forming a nano-pattern, such as the interferometer array 10 and the electrical leads 14a, 14b (the latter being formed with nano-particles of a conductive material, such as gold). See Gibson, Printing Nano Building Blocks, A unique printing method could lead to precise nanofabrication, http://www.technologyreview.com/Nanotech/19387/?a=f (Sep. 17, 2007), hereby incorporated by reference.

The foregoing assembly technique can create multiple groups of uniquely functionalized nanoparticle-nodes, e.g., in the shape of the interferometer ring array 10 illustrated in FIG. 1, which may also then form the rings 12 themselves, or, as a possible alternative, may form a template for guided self-assembly of carbon nano-tubes (“CNTS”) or groups of CNTS.

It will be understood, that in the carbon-based structures, at least, the ballistic scattering length (mean free path) for electrons (i.e., the average distance an electron can travel in a solid before being scattered by an impurity, crystal defect, or thermal vibration) can be relatively very long. This distance should be longer than the path taken, e.g., through one side of the ring 12(s) 12. The size of the Sagnac phase shift is proportional to both the enclosed area of the interferometer array 10 and the rotation rate. To increase the phase shift and hence sensitivity to rotation (necessary for precision measurements), one can use larger rings 12. Since the electron transport through the ring 12 must preserve the quantum mechanical phase of the wave function, the half-circumference of the ring 12 is restricted to being less than the ballistic scattering length. Currently, e.g., high mobility semiconductors at cryogenic temperatures can yield scattering lengths up to 100 microns.

At room temperature, graphene has shown scattering lengths of 1 micron. That distance is increasing every few years with each new generation of experiments and fabrication techniques since it depends on the purity of the material. The purer the material (i.e., free of defects, impurities), the longer the scattering length will be. Initial commercialization of aspects of the disclosed subject matter could be focused on stabilization/positioning applications where the required sensitivity is less stringent than for inertial navigation.

As has been noted above, an electron gyroscope may comprise an array 10, which may be formed by a chain of microscopic interferometer rings 12, radii of 1-10 micrometers, which may be fabricated with nano-technology manufacturing techniques and semiconductor manufacturing micro-lithography technologies, such as in graphene. The electron gyroscope may comprise an array 10 of interferometer rings 12 formed from a sheet of graphene, with each ring 12 in the array 10 having, e.g., a half-circumference shorter in length than the ballistic length for an electron in graphene, and each ring 12 in the array 10 may be less than 20 micrometers in diameter.

While having a much smaller size in comparison to optical rotational motion sensing devices, an electron gyroscope according to aspects of the disclosed subject matter can achieve comparable sensitivity because the Sagnac phase shift for electrons is 100,000-1,000,000 times larger than for light (the exact value depends on the effective mass and Fermi velocity of the material).

The disclosed subject matter could be useful for inertial navigation, positioning, and stabilization applications. It could also be useful in any application in which it is necessary for an object to track its own non-inertial rotational motion. Examples include the following: inertial navigation for vehicles as either a complement to a global positioning system (“GPS”) or in GPS denied areas; image stabilization for video and/or photographic equipment deployed on mobile platforms (cars, airplanes, helicopters, boats, etc. . . . ); positioning control of artillery, particularly gun turrets; radio antennae; spacecraft; video game controllers (such as those for the Nintento Wii); toys; and mobile phones (such as the iPhone). The extremely small size and on chip integration with other circuits can give an electron gyroscope according to aspects of an embodiment of the disclosed subject matter a clear advantage over other technologies. The device could also be used for position control in commercial and industrial robots.

It will be understood that the embodiments described herein are merely exemplary and that a person skilled in the art may make many variations and modifications without departing from the spirit and scope of the invention. All such variations and modifications are intended to be included within the scope of the claimed subject matter.

We claim:

1. In an electron gyroscope comprising an interferometer array including a plurality of rings, the improvement wherein:
the rings are formed of graphene.

2. The electron gyroscope of claim 1, wherein:
each interferometer ring in the interferometer array has a half-circumference shorter in length than the ballistic length for an electron in graphene.

3. A method of making an electron gyroscope, comprising:
forming an interferometer array, which includes a plurality of interconnected interferometer rings, from graphene.

4. The method of claim 3, wherein:
the graphine comprises a single layer of graphene.
